(19) United States
(12) Patent Application Publication
(10) Pub. No.: US 2018/0152176 A1
(43) Pub. Date: May 31, 2018

(54) VOLTAGE AWARE CIRCUIT FOR DUAL VOLTAGE DOMAIN SIGNALS

(71) Applicant: QUALCOMM Incorporated, San Diego, CA (US)

(72) Inventors: Shaoping GE, Cary, NC (US); Chiaming CHAI, Cary, NC (US); Stephen Edward LILES, Apex, NC (US); Rahul Krishnakumar NADKARNI, Cary, NC (US)

(21) Appl. No.: 15/362,784

(22) Filed: Nov. 28, 2016

(51) Int. Cl. H03K 3/013; H03K 3/017

(52) U.S. Cl. CPC H03K 3/013; H03K 3/017

(57) ABSTRACT

Systems and methods for pulse generation in a dual voltage domain include a first and a second voltage aware branch sensitive to a low voltage domain. The first voltage aware branch includes an inverter in the low voltage domain for delaying a leading edge of an output pulse in a high voltage domain from a leading edge of an input pulse in the high voltage domain. The second voltage aware branch includes a delay element in the low voltage domain for extending a pulse width of the output pulse in the high voltage domain from a pulse width of the input pulse.

### FIELD OF DISCLOSURE

Disclosed aspects are directed to integrated circuit designs dual voltage domains. Specifically, exemplary aspects are directed to voltage aware circuits for widening pulse width and delaying leading edge of dual voltage domain signals.

### BACKGROUND

Computer processing systems use several kinds of memory structures. Dual voltage memory array designs, for example, may include memory cells which are placed in a higher voltage domain to improve data retention, while peripheral logic such as write drivers may be placed in a lower voltage domain to reduce their power consumption. Voltage level shifters may be employed to shift signals from the write drivers from one voltage level to another.

In such dual voltage designs, as the low voltage of the low voltage domain goes lower (e.g., with advances in logic technologies), the voltage difference between two voltage domains may increase because advances in memory technologies may not be at the same pace to permit decreases in the high voltage domains that memory arrays are placed in. Device variations at the low voltage domain may start to play more significant roles as the voltage difference increases. This is because signals in the low voltage domain may be slower (i.e., lower frequency) than their counterparts in the high voltage domains. Correspondingly, it becomes difficult for the low voltage domain signals to meet critical timing margins (e.g., setup times, hold times, etc., relative to signals in the high voltage domains).

A conventional approach to handling the dual voltage signals involves adding dedicated voltage sensitive or voltage aware delay elements as well as pulse width extension circuits for signals in the high voltage domain to accommodate their slower counterparts in the low voltage domains. However, the delay elements and pulse width extension circuits are placed in series in conventional designs, which increases the overall delay for timing critical paths; moreover, the delay elements and pulse width extension circuits also add corresponding costs.

Accordingly, there is a need in the art for better solutions for handling dual voltage domain signals, while avoiding the aforementioned drawbacks of conventional designs.

### SUMMARY

Exemplary aspects include systems and methods related to pulse generation in a dual voltage domain. A first and a second voltage aware branch sensitive to a low voltage domain are disclosed. The first voltage aware branch includes an inverter in the low voltage domain for delaying a leading edge of an output pulse in a high voltage domain from a leading edge of an input pulse in the high voltage domain. The second voltage aware branch includes a delay element in the low voltage domain for extending a pulse width of the output pulse in the high voltage domain from a pulse width of the input pulse.

For example, an exemplary aspect is directed to a method of managing a pulse signal in a dual voltage domain. The method comprises receiving an input pulse in a high voltage domain, delaying a leading edge of an output pulse in the high voltage domain from a leading edge of an input pulse in a first voltage aware branch sensitive to a low voltage domain, and extending a pulse width of the output pulse in the high voltage domain from a pulse width of the input pulse in a second voltage aware branch sensitive to the low voltage domain.

Another exemplary aspect is directed to apparatus comprising a first voltage aware branch sensitive to a low voltage domain, configured to delay a leading edge of an output pulse in a high voltage domain from a leading edge of an input pulse in the high voltage domain, and a second voltage aware branch sensitive to the low voltage domain, configured to extend a pulse width of the output pulse in the high voltage domain from a pulse width of the input pulse.

Yet another exemplary aspect is directed to an apparatus comprising a first means sensitive to a low voltage domain, for delaying a leading edge of an output pulse in a high voltage domain from a leading edge of an input pulse in the high voltage domain, and a second means sensitive to the low voltage domain, for extending a pulse width of the output pulse in the high voltage domain from a pulse width of the input pulse.

### BRIEF DESCRIPTION OF THE DRAWINGS

The accompanying drawings are presented to aid in the description of embodiments of the invention and are provided solely for illustration of the embodiments and not limitation thereof.

FIGS. 1-2 illustrate a circuit diagram and a corresponding signal waveform, respectively, for a pulse shaping circuit according to an aspect of this disclosure.

FIG. 3 is a flow-chart illustrating a method of operating the pulse shaping circuit, according to an aspect of this disclosure.

FIG. 4 illustrates an exemplary wireless device 400 in which an aspect of the disclosure may be advantageously employed.

### DETAILED DESCRIPTION

Aspects of the invention are disclosed in the following description and related drawings directed to specific embodiments of the invention. Alternative embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequences of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Exemplary aspects are generally directed to dual voltage circuits for generating pulses in high voltage domains taking into account a voltage differential between the high voltage domain and a low voltage domain. For example, if the voltage of the low voltage domain goes lower, increasing the difference between the high voltage domain and the low voltage domain, then the exemplary circuits correspondingly modify pulse shapes in the high voltage domains. In one aspect the same circuit is used to delay a leading edge of a pulse in the high voltage domain as well as widen a width of the pulse, taking into account the differential between the high voltage domain and the low voltage domain, while avoiding additional delay elements.

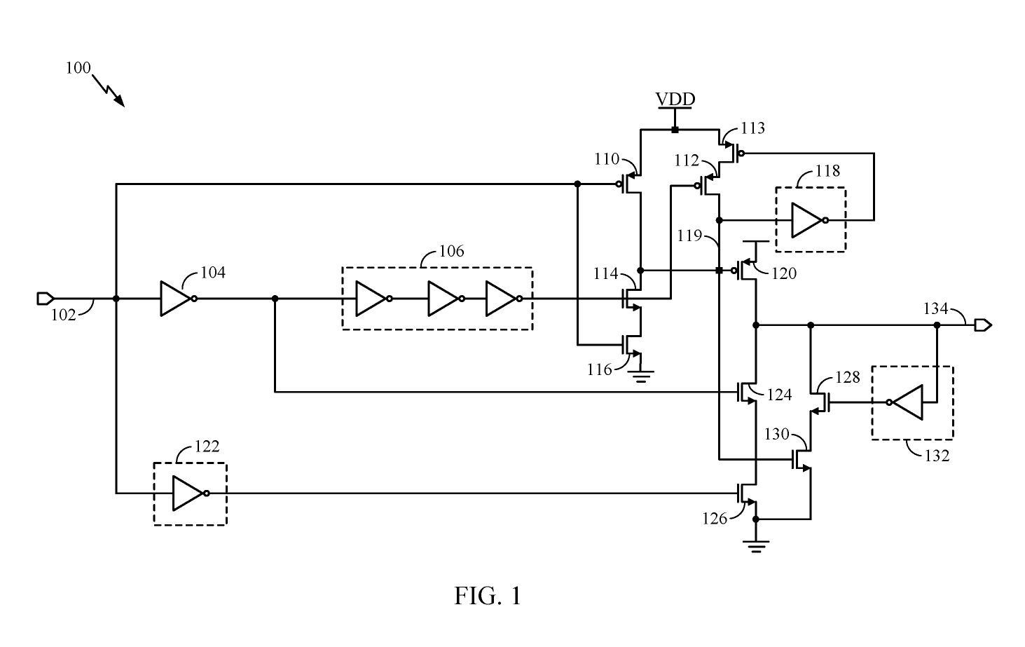

With reference to FIG. 1, circuit 100, as illustrated, is configured to provide voltage aware leading edge delay and voltage aware pulse width widening of an input pulse 102 to generate output pulse 134, both input pulse 102 and output pulse 134 being in a high voltage domain. The voltage awareness of the various components of circuit 100 refers to the characteristic of being sensitive to changes in a low voltage domain relative to the high voltage domain; thus, for example, the leading edge delay and pulse width may both be correspondingly increased if a difference between voltages of the high voltage domain and low voltage domain increases as the voltage of the low voltage domain goes lower.

In this disclosure, circuit 100 is said to comprise two paths or branches. A first branch comprises a low voltage delay element such as a first inverter, shown as inverter 122 in a low voltage domain (e.g., is supplied operating voltage in the low voltage domain, representatively shown in the depiction of FIG. 1 by being enclosed within a box drawn with dashed lines). As will be explained further below, the first branch may be used to generate a leading edge of output pulse 134 by applying a voltage aware leading edge delay to input pulse 102.

Circuit 100 also includes a second branch which may be used to generate a width of output pulse 134 by applying a voltage aware pulse width widening of input pulse 102. The second branch comprises a second inverter, shown as inverter 104 in the high voltage domain and a delay element shown as low voltage domain delay element 106. In FIG. 1, low voltage domain delay element 106 is shown as comprising three inverters connected in series, while in general, low voltage domain delay element 106 may be formed with an odd number of inverters connected in series. Low voltage domain delay element 106 is also shown within dashed boxes to represent that the components therein are supplied with operating voltage in the low voltage domain. In exemplary aspects, low voltage domain delay element 106 provides the voltage aware pulse width widening path for input pulse 102, to generate output pulse 134 with a wider pulse width in the event that the voltage of the low voltage domain goes lower.

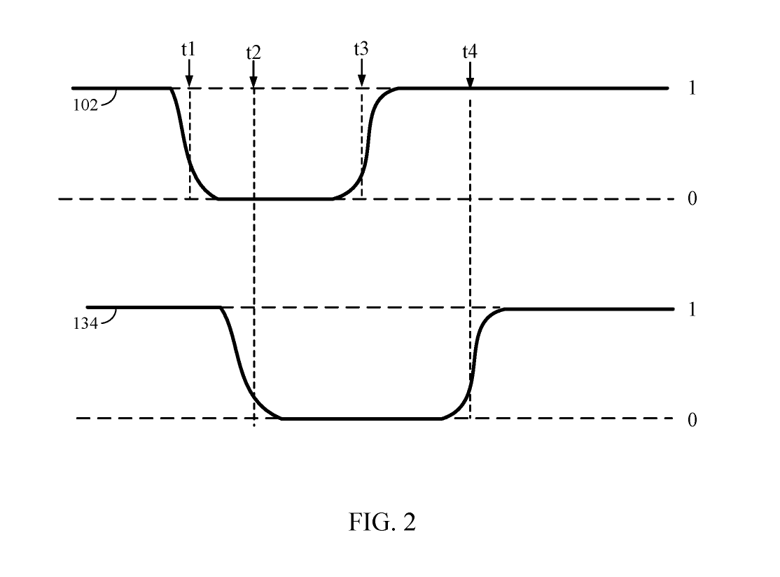

The operation of circuit 100 will now be described with combined reference to the structure of circuit 100 in FIG. 1 and the wave forms for input and output pulses 102 and 134, respectively, shown in FIG. 2. Thus, with combined reference to FIGS. 1-2, input pulse 102 is initially high or logic “1”, which causes the output of inverter 122 in the first branch to be low, turning off n-type device or n-channel field effect transistor (NFET) 126. The initial high voltage on pulse 102 also turns off p-type device or p-channel field effect transistor (PFET) 110. Initially, NFETs 114 and 116 are on, which pulls the gate of PFET 120 ground causing PFET 120 to turn on and pull up output pulse 134 to an initial high voltage level or logic “1”.

At time t1, input pulse 102 falls, and after the time delay associated with the low voltage domain inverter 122, the output of inverter 122 will start to rise, which is a slow path (due to inverter 122 operating in the low voltage domain) that will eventually cause NFET 126 to turn on. With falling input pulse 102, the output of high voltage domain inverter 104 in the second branch will rise faster and NFET 124 will turn on before NFET 126 turns on from the slower path through the first branch. The combination of NFETs 124 and 126 will pull down output pulse 134, which will cause the leading edge of output pulse 134 to fall to logic “0” at time t2. Since the slower path through NFET 124 is controlled by low voltage domain inverter 122, the corresponding fall of output pulse 134 at time t2 is also controlled by low voltage domain inverter 122. Thus, the first branch comprising low voltage domain inverter 122 provides a voltage aware leading edge delay for the leading edge of output pulse 134.

With continued combined reference to FIGS. 1-2, aspects of voltage aware pulse width widening will be explained. Once input pulse 102 falls to “0” at time t1, it remains there until time t3 or in other words, for the duration of the pulse width of input pulse 102: t3−t1. During this duration, pulse width widening functionality of the second branch goes into effect in the following manner. When input pulse 102 starts to rise at time t3, PFET 110 is turned off and NFET 116 is turned on. However, there is a delay predominantly caused by low voltage domain delay element 106 in the path of input pulse 102 (after passing through the faster high voltage domain inverter 104) before the high logic level on input pulse 102 appears at NFET 114 to turn on NFET 114 as well. Once NFETs 114 and 116 are turned on, a path to ground is established through NFETs 114 and 116, causing PFET 120 to turn on and thus, pull up output pulse 134 to “1” at time t4. Correspondingly, the pulse width of output pulse 134 (t4−t2) is seen to be extended in comparison to the pulse width of input pulse 102 (t3−t1), wherein the pulse width extension is provided by the second path, and specifically by low voltage domain delay element 106, in a voltage aware manner. If the low voltage falls lower and increases the difference in voltage between the high voltage domain and the low voltage domain, then the delay through low voltage domain delay element 106 correspondingly increases, thus extending the pulse width of output pulse 134 even more.

In an aspect of circuit 100, it is possible for the late arriving signals through the above-mentioned low voltage domain delay elements to cause fluctuations in output pulse 134 while it is in the low logic level (and more specifically, during the duration of time between t3 and t4 from when input pulse 102 rises to when output pulse 134 rises).

To prevent such fluctuations, latches 118 and 132 are provided. Latch 118 includes a feedback path comprising PFETs 112 and 113 which keeps PFET 120 turned off, and latch 132 involves NFETS 128 and 130 to keep output pulse 134 pulled low for the duration of the low logic level of output pulse 134. During this period NFET 130 is turned on, providing a path to ground for output pulse 134. PFET 110 is turned on until time input signal 102 starts to rise at time t3. PFET 112 is on while input signal 102 is low. Once input signal 102 starts to rise at time t3, after a time delay through low voltage domain delay element 106, PFET 112 will turn off, thus disassociating the influence of latch 118, following which, output pulse 134 will be allowed to rise at time t4. Thus, during the time between t3 and t4, any fluctuations on input pulse 102 will not affect output pulse 134.

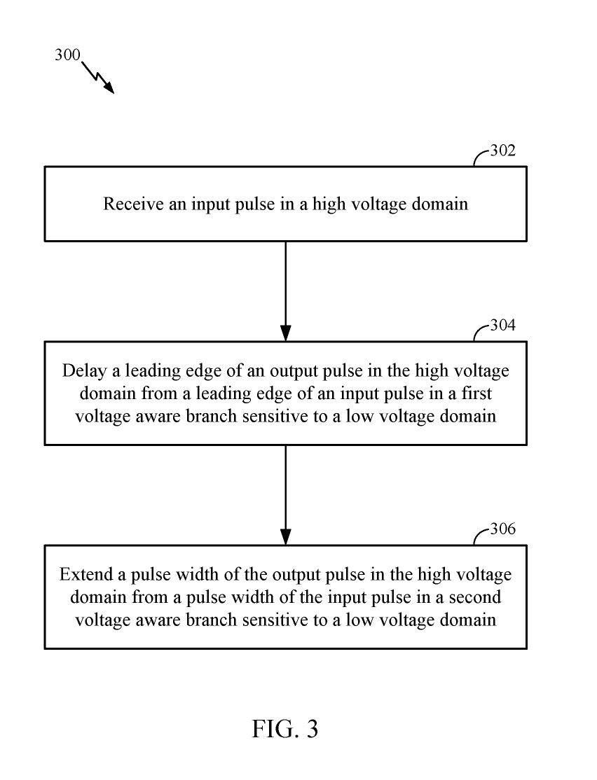

It will be appreciated that exemplary aspects include various methods for performing the processes, functions and/or algorithms disclosed herein. For example, as illustrated in FIG. 3, an exemplary aspect can include a method (300) of method of managing a pulse signal in a dual voltage domain.

Block 302 comprises receiving an input pulse in a high voltage domain. For example, input pulse 102 is received in the high voltage domain.

Block 304 comprises delaying a leading edge of an output pulse in the high voltage domain from a leading edge of an input pulse, in a first voltage aware branch sensitive to a low voltage domain. For example, the leading edge of output pulse 134 is delayed from the leading edge of input pulse 102 using the first branch comprising inverter 122 in the low voltage domain.

Block 306 comprises extending a pulse width of the output pulse in the high voltage domain from a pulse width of the input pulse in a second voltage aware branch sensitive to the low voltage domain. For example, the pulse width of output pulse 134 is widened using the second branch comprising the low voltage domain delay element 106.

In some aspects, method 300 may further comprise avoiding fluctuations on output pulse 134 for a duration of the pulse width of output pulse 134, with a first latch coupled to the first voltage aware branch (e.g., latch 118 including a feedback path comprising PFETs 112 and 113 which keeps PFET 120 turned off) and a second latch coupled to the second voltage aware branch (e.g., latch 132 including NFETS 128 and 130 to keep output pulse 134 pulled low for the duration of the low logic level of output pulse 134). As discussed above, in method 300, a delay on the leading edge of the output pulse and the pulse width of the output pulse may be increased if a voltage of the low voltage domain decreases in comparison to a voltage of the high voltage domain.

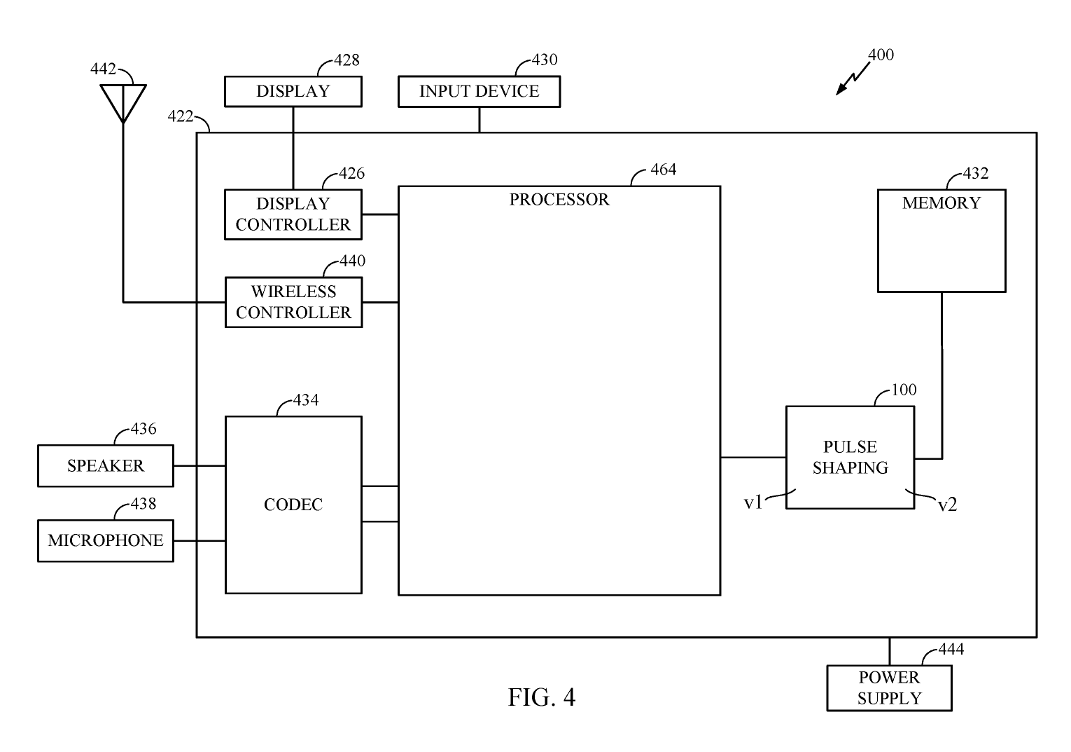

Referring now to FIG. 4, a block diagram of a particular illustrative embodiment of a wireless device configured to perform method 300 of FIG. 3 is depicted and generally designated 400. Wireless device 400 includes processor 464 coupled to memory 432. Wireless device 400 is also shown to include exemplary circuit 100 for pulse shaping as discussed with relation to FIG. 1, where circuit 100 may receive voltages in a low voltage domain (v1) a high voltage domain (v2) and provide pulse shaping in a voltage aware manner as discussed above. One or more arrays of bit cells in memory 432 may be configured in a voltage island corresponding to the high voltage domain pulses shaped in circuit 100 may be used for controlling memory 432 in some cases. Circuit 100 is shown to representatively be included between processor 464 and memory 432, but it will be understood that this is merely for schematically representing aspects of this disclosure and not to be construed as a limitation in the placement/routing of hardware blocks pertaining to circuit 100.

FIG. 4 also shows display controller 426 that is coupled to processor 464 and to display 428. Coder/decoder (CODEC) 434 (e.g., an audio and/or voice CODEC) can be coupled to processor 464. Other components, such as wireless controller 440 (which may include a modem) are also illustrated. Speaker 436 and microphone 438 can be coupled to CODEC 434. FIG. 4 also indicates that wireless controller 440 can be coupled to wireless antenna 442. In a particular embodiment, processor 464, display controller 426, memory 432, CODEC 434, and wireless controller 440 are included in a system-in-package or system-on-chip device 422.

In a particular embodiment, input device 430 and power supply 444 are coupled to the system-on-chip device 422. Moreover, in a particular embodiment, as illustrated in FIG. 4, display 428, input device 430, speaker 436, microphone 438, wireless antenna 442, and power supply 444 are external to the system-on-chip device 422. However, each of display 428, input device 430, speaker 436, microphone 438, wireless antenna 442, and power supply 444 can be coupled to a component of the system-on-chip device 422, such as an interface or a controller.

It should be noted that although FIG. 4 depicts a wireless communications device, processor 464, and memory 432 may also be integrated into a set-top box, a music player, a video player, an entertainment unit, a server, a navigation device, a personal digital assistant (PDA), a fixed location data unit, a mobile phone, a smart phone, or a computer.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for managing a pulse signal in a dual voltage domain. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method of managing a pulse signal in a dual voltage domain, the method comprising:
receiving an input pulse in a high voltage domain;
delaying a leading edge of an output pulse in the high voltage domain from a leading edge of an input pulse in a first voltage aware branch sensitive to a low voltage domain; and
extending a pulse width of the output pulse in the high voltage domain from a pulse width of the input pulse in a second voltage aware branch sensitive to the low voltage domain.

2. The method of claim 1, wherein the first voltage aware branch comprises a first inverter in the low voltage domain.

3. The method of claim 1, wherein the second voltage aware branch comprises a low voltage domain delay element including an odd number of inverters connected in series.

4. The method of claim 3, wherein the second voltage aware branch further comprises a second inverter in the high voltage domain.

5. The method of claim 1, comprising avoiding fluctuations in the output pulse for a duration of the pulse width of the output pulse, with a first latch coupled to the first voltage aware branch and a second latch coupled to the second voltage aware branch.

6. The method of claim 1 comprising increasing the delay on the leading edge of the output pulse if a voltage of the low voltage domain decreases in comparison to a voltage of the high voltage domain.

7. The method of claim 1 comprising increasing the pulse width of the output pulse if a voltage of the low voltage domain decreases in comparison to a voltage of the high voltage domain.

8. An apparatus comprising:
a first voltage aware branch sensitive to a low voltage domain, configured to delay a leading edge of an output pulse in a high voltage domain from a leading edge of an input pulse in the high voltage domain; and
a second voltage aware branch sensitive to the low voltage domain, configured to extend a pulse width of the output pulse in the high voltage domain from a pulse width of the input pulse.

9. The apparatus of claim 8, wherein the first voltage aware branch comprises a first inverter in the low voltage domain.

10. The apparatus of claim 1, wherein the second voltage aware branch comprises a low voltage domain delay element including an odd number of inverters connected in series.

11. The apparatus of claim 10, wherein the second voltage aware branch further comprises a second inverter in the high voltage domain.

12. The apparatus of claim 8, comprising a first latch coupled to the first voltage aware branch and a second latch coupled to the second voltage aware branch, configured to avoid fluctuations in the output pulse during the duration of the pulse width of the output pulse.

13. The apparatus of claim 8, wherein the first voltage aware branch is configured to increase the delay on the leading edge of the output pulse if a voltage of the low voltage domain decreases in comparison to a voltage of the high voltage domain.

14. The apparatus of claim 8, wherein the second voltage aware branch is configured to increase the pulse width of the output pulse if a voltage of the low voltage domain decreases in comparison to a voltage of the high voltage domain.

15. The apparatus of claim 8 integrated into a device selected from the group consisting of a set-top box, a music player, a video player, an entertainment unit, a server, a navigation device, a personal digital assistant (PDA), a fixed location data unit, a mobile phone, a smart phone, and a computer.

16. An apparatus comprising:
first means sensitive to a low voltage domain, for delaying a leading edge of an output pulse in a high voltage domain from a leading edge of an input pulse in the high voltage domain; and
second means sensitive to the low voltage domain, for extending a pulse width of the output pulse in the high voltage domain from a pulse width of the input pulse.

17. The apparatus of claim 16, wherein the first means comprises a first means for inverting the input pulse in the low voltage domain.

18. The apparatus of claim 16, wherein the second means comprises a second means for inverting the input pulse in the low voltage domain.

19. The apparatus of claim 18, wherein the second means further comprises a second means for inverting the input pulse in the high voltage domain.

20. The apparatus of claim 16, comprising means for avoiding fluctuations in the output pulse for a duration of the pulse width of the output pulse.

21. The apparatus of claim 16, comprising means for increasing the delay on the leading edge of the output pulse if a voltage of the low voltage domain decreases in comparison to a voltage of the high voltage domain.

22. The apparatus of claim 16 comprising means for increasing the pulse width of the output pulse if a voltage of the low voltage domain decreases in comparison to a voltage of the high voltage domain.
